(19) United States
(12) Patent Application Publication
(10) Pub. No.: US 2009/0096469 A1
(43) Pub. Date: Apr. 16, 2009

(54) Determining Key Resistance Values

(75) Inventors: John Milburn, Georgetown, TX (US); Emmanuel Enrique Lopez, Georgetown, TX (US)

Correspondence Address: FISH & RICHARDSON P.C., P.O BOX 1022, Minneapolis, MN, 55440-1022, US

(73) Assignee: Michael Laranang, Round Rock, TX (US)

(21) Appl. No.: 12/243,417

(22) Filed: Oct. 1, 2008

Related U.S. Application Data
(60) Provisional application No. 60/977,141, filed on Oct. 3, 2007.

(51) Int. Cl. G01R 27/02

(52) U.S. Cl. 324/691

(57) ABSTRACT

A system for determining a correct resistor key value for a vehicle equipped with a theft deterrent system includes a test key having two electrical contacts positioned to engage respective contacts of a vehicle theft deterrent system when the test key is inserted into a vehicle ignition key receptacle, and a scanner connected to the electrical contacts of the test key. The scanner includes a controller configured to sequentially apply a series of discrete, fixed electrical resistance values across the key contacts while the key is inserted in the receptacle, to determine which resistance value corresponds to a resistance value required to activate the ignition.

### CROSS-REFERENCE TO RELATED APPLICATIONS

This U.S. patent application claims priority under 35 U.S.C. §119(e) to U.S. Provisional Application 60/977,141, filed on Oct. 3, 2007. The disclosure of the prior application is considered part of the disclosure of this application and is hereby incorporated by reference in its entirety.

### TECHNICAL FIELD

This invention relates generally to vehicle anti-theft systems (VATS) and more particularly to a system and method for determining the required resistor value for a key to start a vehicle equipped with a VATS security system commonly used by General Motors.

### BACKGROUND

VATS (vehicle anti-theft system) security keys were widely used by General Motors between 1986 and 2005. VATS security keys have a resistor pellet mounted in the center of the key with one of 15 distinct resistor values. Every VATS system equipped vehicle is set to one of these 15 resistor values. The VATS security system passes voltage through the resistor mounted in the key when it is inserted into the ignition, then compares the voltage to the stored system value to determine if the correct key is present. The VATS security key therefore provides an additional layer of authorization beyond the mechanical cuts of an ignition key, by also requiring the correct resistor value to be present in order to start the vehicle. In contrast, if the wrong resistor value is presented to the vehicle, the vehicle locks out the driver for a period of three minutes before they can attempt to start the vehicle again.

The GM VATS system's main function is to verify that the correct ignition key also has the correct resistor pellet value to start the vehicle. When the correct VATS key ensemble is in the ignition and cycled on, the theft deterrent module allows the fuel pump to be enabled and the starter to engage. If the incorrect key is used the theft deterrent module would recognize the wrong resistor pellet and not enable the fuel pump and the starter. The theft deterrent module will also force a 3 minute timeout not allowing any key, not even the correct key, to start the vehicle until it has timed out for the entire 3 minutes.

Determining the resistor pellet value from an existing VATS key is fairly simple by using a ohm-meter or other tools on the market that measure electrical resistance. However when there are no existing keys available to read the resistance off of, the most common tool used to determine the correct resistor necessary for a vehicle is one in which the user manually selects from a bank of 15 standard resistance values, presenting each value one at a time to identify the correct value of a VATS system through trial and error. There are 15 standard values of resistance and they are as follows:

```
  1) = 402 ohms
  2) = 523 ohms
  3) = 681 ohms
  4) = 887 ohms
  5) = 1,130 ohms
  6) = 1,470 ohms
  7) = 1,870 ohms
  8) = 2,370 ohms
  9) = 3,010 ohms
10) = 3,740 ohms
11) 4,750 ohms
12) 6,040 ohms
13) 7,500 ohms
14) 9,530 ohms
15) 11,800 ohms
```

If the technician has to go through all 15 values with a 3-minute lockout in between, it could take up to an hour to identify the correct resistance pellet. This has frustrated the automobile aftermarket industry for years. There exists a need not met by the state of the art, to reduce the time for determining the resistor value of a VATS system used commonly on GM vehicles.

### SUMMARY

One aspect of the invention features a system and method for determining the resistor value of a VATS security system by General Motors. A microprocessor-controlled system and display electronics interfaces with a VATS-equipped vehicle's ignition system, systematically presenting each of the resistor values in short time intervals in such a manner as to avoid a 3-minute lock out condition, while determining the correct resistor value for a given VATS system. There are provisions to monitor the VATS system status via (3) three methods, as follows:
1) Data bus communications filtering through the industry standard OBDII connector
2) Security data signal status monitoring through the industry standard OBDII connector
3) Optical monitoring of the Security signal light on the instrument cluster

The controller and display system is coupled to a test key as a method for presenting the varied resistor values to the VATS system. The test key itself has negligible resistance but has electrical connectors to receive the varied resistor inputs from the controller and display system. The test key may be cut to mechanically turn in the vehicle's ignition. Once the key is turned to the ON position, the controller and display system will start presenting the various set of resistors systematically to the VATS security system. While the array of resistors is being presented, the system monitors the VATS system through one or more of the monitoring methods described previously to recognize when the correct resistor has been detected, or in some cases if the incorrect resistor has triggered a lockout condition.

The system stops the scan when it detects either of these conditions and identifies the resistor and whether it successfully passed or caused a lockout. If it passed, the resistor value is then output on the LED display, indicating a pass condition via a green LED and audible tone. If it failed, the resistor value is output on the LED display and indicating a fail condition via a red LED display and different audible tone pattern.

This enables the user to selectively eliminate one or more of the resistor values from the scan sequence. This would enable the resistor that caused a failure on a previous scan to be eliminated from the scan sequence on subsequent scans. This is done by an array of dip switches labeled for the 15 resistor values, which disconnect the resistor from the scan circuit.

In the event of an incorrect resistor reading resulting in a lockout, a 3 minute timer is initiated for a visual indicator of how much time has elapsed and/or left in the lockout period.

Potential advantages of the present invention over the known prior art include but are not limited to 1) “Plug and play”—no installation with no need to splice wires; 2) The ability to quickly identify the correct key resistor pellet needed to start a VATS security-equipped vehicle; and 3) The ability to select from different system status input methods to accommodate the diverse schemes of VATS system implementations on various vehicles.

A preferred implementation features four components: 1) a power/signal OBD2 cable with 9 pin D-sub connector, 2) an optical cable with suction cup, housing a cds photo resistor and red LED for tracking, 3) a metal ignition key with no pellet and no rubber head to be placed in a 2 sided pcb with connectors for Scan key output, and 4) a 12VDC/cigarette lighter plug used when the monitor input method used is the optical mode.

The invention may be configured for use with General Motors vehicles that use a VATS security system, to determine the resistor pellet value required by the security system to enable the key to start the vehicle. By using a test key coupled to a resistor bank and presenting different resistor values in short time durations to the VATS security system, the scanner is able to cycle through the known set of resistors until it determines the correct value, while also minimizing the triggering of 3-minute lockouts as a result of an incorrect resistor reading. Because there are several types of VATS theft deterrent system implementations in use on GM vehicles, the system includes multiple means of monitoring the VATS security system status, including the industry standard OBDII diagnostic connector as well as an optical sensor that monitors the status of the VATS security light on the instrument cluster. This can significantly reduces the time it takes to determine the correct key for a VATS security-enabled GM vehicle.

The details of one or more embodiments of the invention are set forth in the accompanying drawings and the description below. Other features, objects and advantages of the invention will be apparent from the description and drawings, and from the claims

### BRIEF DESCRIPTION OF THE DRAWINGS

FIG. 1 shows a block diagram of the master control and display module with the following input and output cables and modules scan key output module and cable, optical input module, data bus communications, power, and direct data input OBD2 cable.

FIG. 2 shows an example of the wiring scheme and setup in the Data bus communications and direct OBD2 mode. The connections are as follows: data bus communications, power and direct data input OBD2 cable, scan key output cable

FIG. 3 shows an example of the wiring scheme and setup in the optical sensor mode. The connections are as follows: cigarette lighter/accessories plug providing 12VDC power, optical sensor input module, scan key output cable.

FIG. 4 shows the optical sensor and tracking LED module and its 4-pin male din plug. The module encompasses 2 electronic devices: CDS photo resistor, red LED, rubber molded suction cup housing, 4 conductor cable with #26 gauge wire and 4 pin din plug assembly.

FIG. 5 shows the VATS test key with holder adapter and circuit isolation protection. This adapter is made up of the following metal VATS key (interchangeable), 2 pieces of pcb boarding, 2 wire contacts for 2 conductor 26 gauge wire, cable assembly 2 metal spring pellet contacts.

FIG. 6 illustrates the controller and display system. The following is a list of external components: power input connector optical sensor input connector, scan key output, pellet display, cycle LED, pass LED, fail LED, 3 minute countdown timer, pellet eliminator, power on indicator, key reader input, vehicle power indicator, audio signal power on switch, audio on/off switch, high/low speed scan switch, start scan button, reset button, data signal selector, optical sensitivity adjustment.

Like reference numbers indicate like elements

### DETAILED DESCRIPTION

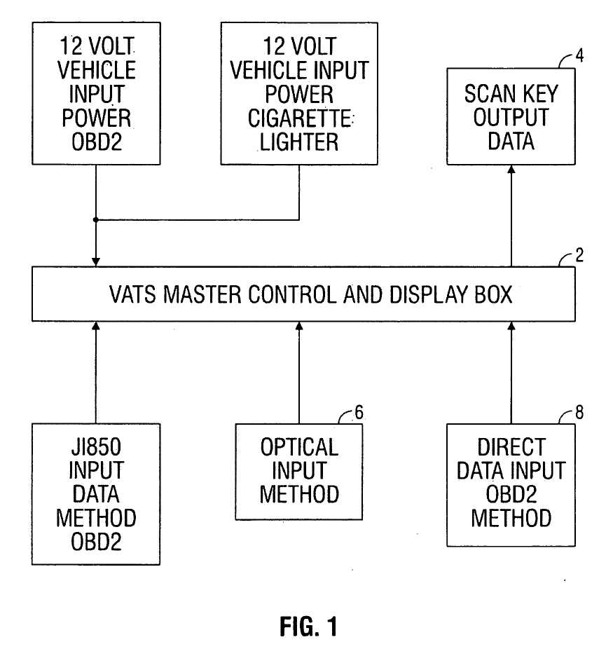

The system as depicted in FIG. 1 includes four components: VATS master control and display box 19 scan key output module 21, optical input module 22, and data bus, input power, and direct data input 23.

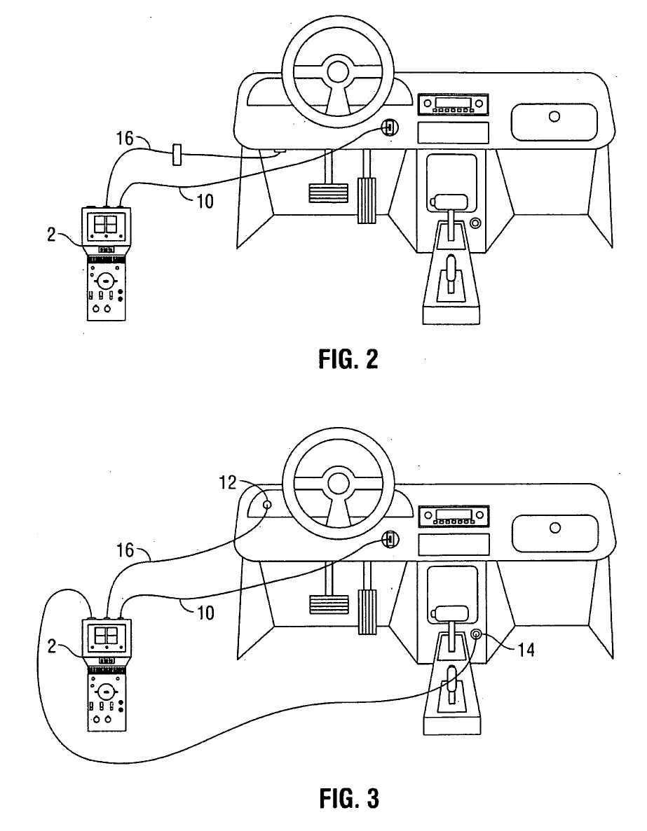

VATS master control and display box 19 is a multi-processor scan tool capable of receiving input and output data from VATS-equipped vehicles. FIG. 2 shows an example of the J1850 data bus and direct data link applications as they would be connected to a vehicle using the OBD2 cable 3 where it would receive either the J1850 signal or the direct security data signal, and scan key output cable 4 where it would send the output scan data to be inserted into the ignition of the vehicle.

FIG. 3 shows VATS master control and display box 19 with the optical sensor module 8 and its connection requirements for vehicles not having an OBD2 diagnostic connector port. The means for power in this application is through the cigarette lighter or accessory power port of the vehicle using the 12VDC plug 7. The scan key output cable 9 where it would send the output scan data to be inserted into the ignition of the vehicle. The optical sensor input module 8 where its used to pick up the security light from the instrument cluster via a suction cup housing a CDS photo resistor and a red LED for tracking the position of the security lamp inside the instrument cluster.

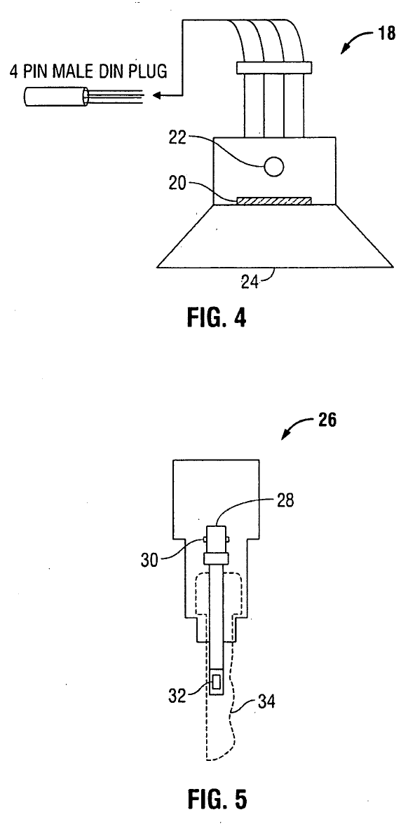

FIG. 4 shows illustration of the optical sensor and LED tracking module 11 with an illustration of its electronics inside the rubber molded suction cup that is approximately 3.0 mm in size. There are essentially 2 electronic components the optical sensor LED tracking module 11, none being the cds photo resistor 14 and the pother the red LED 15 which are embedded in the rubber molded suction cup housing 16. This module and its components are used to track and sense the security lamp inside the instrument clusters of early model GM vehicles.

FIG. 5 shows the VATS metal key holder with circuit isolation protection 18. This adapter contains the following parts. 2 pieces of pcb boarding 21, 2 wire contacts for 4 ft. 2 conductor 26 gauge wire 22 cable assembly 2 metal spring pellet contacts 23. These parts create the housing and support for the interchangeable VATS keys 20, whether they be double or single sided.

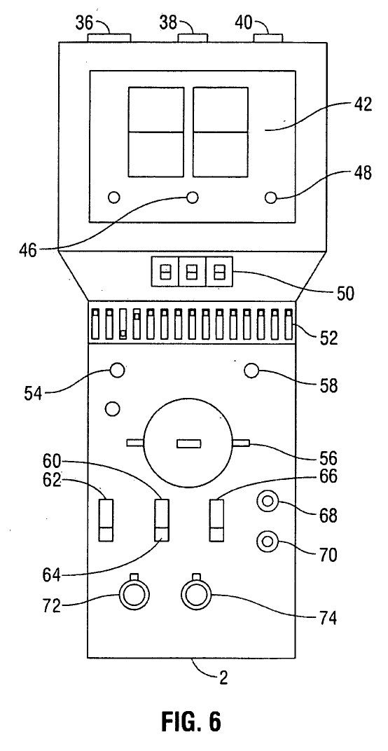

FIG. 6 shows the scanner 1 with all its nomenclature. The power input connector 4 allows either a OBD2 cable assembly or a cigarette lighter cable assembly to be connected to the scanner. The optical sensor input 5 provides the scanner with light pulses produced by a lamp inside the instrument cluster of the vehicle. These pulses are used for calculation in determining pass and fail criteria. The scan key output 6 connector is used to present through the ignition of the vehicle the 15 values of VATS resistor pellets at a certain speed to develop the voltage and current drops needed for its critical calculations. The large dual 7 segment LED display 7 provides the indication of what pellet was selected during a scan sequence and displays either a pass or fail selection. The cycle red LED flashes on and off at the same time as the data coming in from the OBD2 connector 4 or the optical sensor connector 5. The pass 9 green LED is an indictor used when the scanner accepts the correct input and output data signals and the vehicle under test is able to start. The fail 10 red LED indicator illuminates when a wrong resistor pellet has triggered a 3 minute timeout on the theft deterrent module. The 3 minute countdown clock 11 gets initiated when the theft deterrent module starts the 3 minute count down. The pellet eliminator 12 is used to select or deselect any of the 15 resistor values that are used in the scan cycle. If a fail scan occurred the pellet number can be removed from the next scan cycle so that it is not repeated again. The power on 13 indicator is a yellow LED illuminating when internal power as been switched on. The key reader input 14 socket is used to read any of the VATS keys by inserting the key into it. This can be done even if external power is not present. The vehicle power 15 indicator comes on as soon as the OBD2 cable or cigarette lighter adapter is plugged into the scanner. The audio 16 is provided by a piezo element on the scanners circuit board. This provides an oscillating sound when a pass condition is present and a steady sound when a fail condition is received. The power on 17 switch turns on internal power supplied by 6 alkaline 1.5 volt batteries totaling 9VDC. The audio on/off 18 switch allows operator to use the audio sound or not during a scan sequence. The scan speed high/low 19 switch allows the operator to select an adjustment for the sensitivity of the scan speed to prevent errors and lock on. The start scan button 20 is pushed to start the scanning process. The reset scan 21 is used to clear the internal electronics and clocks in the system. The data signal selector 22 is used to set the inputs and outputs from the vehicle to the proper positions for scanning. The ‘A’ position is used for OBD2 direct data, ‘B’ position is used for Data bus communications, and ‘C’ is used for optical data. The optical sensitivity 23 adjustment is used for tracking the correct lamp inside the instrument cluster and also for producing the necessary signals for scan data when using the appropriate setup.

To attach the scanner to the vehicle the OBD2 connector is either plugged into the OBD2 diagnostic connector or the 12V adapter is plugged into cigarette lighter/accessory socket of the vehicle. The scan key cable has to be inserted into the ignition switch of the vehicle and if the optical sensor needs to be used it will have to be attached to the instrument cluster aimed at the appropriate security lamp.

It will be understood that various modifications may be made without departing from the spirit of the scope of the invention. For example, while the invention has been described with reference to VATS systems for vehicles, it is equally applicable to any application that uses VATS tools. Accordingly, other embodiments are within the scope of the following claims.

What is claimed is:

1. A system for determining a correct resistor key value for a vehicle equipped with a theft deterrent system, the system comprising
a test key having two electrical contacts positioned to engage respective contacts of a vehicle theft deterrent system when the test key is inserted into a vehicle ignition key receptacle; and
a scanner connected to the electrical contacts of the test key, the scanner including a controller configured to sequentially apply a series of discrete, fixed electrical values across the key contacts while the key is inserted in the receptacle, to determine which electrical value corresponds to a resistance value required to activate the ignition.

2. The system of claim 1, further comprising a pass/fail sensor responsive to a vehicle ignition pass/fail indicator.

3. The system of claim 1, wherein the scanner further comprises a vehicle diagnostic port adaptor configured to interface with a diagnostic port of the vehicle to monitor pass/fail status as the electrical values are sequenced.

4. The system of claim 1, wherein the fixed electrical values are discrete electrical resistances.

5. The system of claim 4, wherein the scanner includes a series of discrete resistors, each resistor having a resistance corresponding to one of the discrete electrical resistances.

6. The system of claim 4, wherein the scanner further comprises a series of switches, each switch corresponding to one of the discrete resistances and operable to remove its corresponding resistance from the resistance sequence.

7. The system of claim 1, wherein the scanner is configured to time the sequencing of the electrical values to prevent automatic disabling of the ignition by the theft deterrent system.

8. The system of claim 1, wherein the scanner includes a display that indicates the result of the correct resistor determination.

9. A method of determining a correct resistor key value for a vehicle equipped with a theft deterrent system, the method comprising
inserting a test key into an ignition key receptacle of the vehicle, the test key having two electrical contacts positioned to engage respective contacts of the vehicle theft deterrent system; and
activating a scanner connected to the electrical contacts of the test key, to sequentially apply a series of discrete, fixed electrical values across the key contacts while the key is inserted in the receptacle, to determine which electrical value corresponds to a resistance value required to activate the ignition.

10. The method of claim 9, further comprising monitoring a pass/fail sensor responsive to a vehicle ignition pass/fail indicator.

11. The method of claim 9, wherein the scanner further comprising, prior to activating the scanner, connecting the scanner to a vehicle diagnostic port of the vehicle to monitor pass/fail status as the electrical values are sequenced.

12. The method of claim 9, wherein activating the scanner sequentially applies a series of discrete, fixed resistance values across the key contacts.

13. The method of claim 9, wherein activating the scanner sequentially operates a series of switches, each switch corresponding to one of the discrete electrical values.

14. The method of claim 9, wherein the scanner is configured to time the sequencing of the electrical values to prevent automatic disabling of the ignition by the theft deterrent system.

15. The method of claim 9, comprising monitoring a display of the scanner for a result of the correct resistor determination.
